(19) United States
(12) Patent Application Publication
(10) Pub. No.: US 2026/0204520 A1
(43) Pub. Date: Jul. 16, 2026

(54) BONDING METHOD USING SURFACE ACTIVATION PLASMA TREATMENT

(71) Applicant: Tokyo Electron Limited, Tokyo (JP)

(72) Inventors: Andrew Tuchman, Albany, NY (US); Christopher Michael Netzband, Albany, NY (US); Ilseok Son, Albany, NY (US); Sophia Madelone, Ballston Spa, NY (US); Angelique Raley, Albany, NY (US)

(21) Appl. No.: 19/018,597

(22) Filed: Jan. 13, 2025

(51) Int. Cl. H01J 37/32; H10W 72/00

(52) U.S. Cl. CPC H01J 37/32449; H01J 37/32724; H01J 2237/336; H10W 72/07331

(57) ABSTRACT

A method for bonding wafers includes receiving a first wafer and a second wafer, the first wafer including a first bonding layer, the second wafer including a second bonding layer. The method further includes performing a surface activation plasma (SAP) treatment on the first bonding layer of the first wafer to form a first treated layer by exposing the first bonding layer to a plasma, the SAP treatment introducing nitrogen groups including inactive nitrogen termination sites on an exposed surface of the first bonding layer. And the method further includes striking the first wafer to bond the first treated layer of the first wafer with the second wafer to form a bonded wafer.

### TECHNICAL FIELD

The present invention relates generally to a system and method for bonding, and, in particular embodiments, to a system and method for bonding using a surface activation plasma treatment to increase nitrogen concentration of bonding layers.

### BACKGROUND

In wafer-to-wafer bonding processes used in semiconductor manufacturing, fusion bonding is employed to flip a device wafer over for back-side processing. However, this fusion bonding process can introduce distortions in the device wafer pattern, leading to non-linear deformations. These distortions can cause misalignments in subsequent lithography patterns and potentially result in missed connections. Further, surface activation plasma (SAP) parameters optimized for high bonding energy can lead to increased distortion and wafer warpage after bonding. This presents challenges in maintaining precise alignment and connections in multilayer semiconductor devices, particularly in processes such as backside power delivery networks (BS-PDN).

### SUMMARY

In accordance with an embodiment of this disclosure, a method for bonding wafers includes receiving a first wafer and a second wafer, the first wafer including a first bonding layer, the second wafer including a second bonding layer. The method further includes performing a surface activation plasma (SAP) treatment on the first bonding layer of the first wafer to form a first treated layer by exposing the first bonding layer to a plasma, the SAP treatment introducing nitrogen groups including inactive nitrogen termination sites on an exposed surface of the first bonding layer. And the method further includes striking the first wafer to bond the first treated layer of the first wafer with the second wafer to form a bonded wafer.

In accordance with another embodiment of this disclosure, a method of bonding includes receiving a first wafer in a surface activation plasma (SAP) system, the first wafer including a bonding layer disposed over an underlying layer, and generating a nitrogen plasma configured to activate a surface. The method further includes exposing the bonding layer to the nitrogen plasma to form a surface activated bonding layer including nitrogen groups, where the nitrogen groups include inactive nitrogen termination sites, and rinsing the surface activated bonding layer with deionized water (DIW), where the rinsing converts the surface activated bonding layer to a treated bonding layer including hydroxyl groups and the nitrogen groups. And the method further includes bonding the treated bonding layer with the nitrogen groups and the hydroxyl groups to a second wafer.

And in accordance with yet another embodiment of this disclosure, a system for semiconductor processing includes a vacuum pump coupled to a surface activation plasma (SAP) chamber, the SAP chamber including a wafer holder and a top electrode, and a gas system coupled to the SAP chamber through a gas inlet, the gas system including a first precursor gas, a second precursor gas, and a purging gas. And the system further includes a temperature control system coupled to the wafer holder, an RF power supply electrically coupled to the top electrode, and a controller coupled to the RF power supply, the vacuum pump, the gas inlet, the gas system, the wafer holder, the SAP chamber, and a memory storing instructions to be executed in the controller. The instructions when executed cause the controller to receive a first wafer on the wafer holder, the first wafer including a bonding layer disposed over an underlying layer, generate a nitrogen plasma using the gas system and the RF power supply, the nitrogen plasma configured to activate a surface. The instructions when executed further cause the controller to expose the bonding layer to the nitrogen plasma to form a surface activated bonding layer including nitrogen groups, where the nitrogen groups include inactive nitrogen termination sites, and rinse the surface activated bonding layer with deionized water (DIW), where the rinse converts the surface activated bonding layer to a treated bonding layer including hydroxyl groups and the nitrogen groups. And the instructions when executed further cause the controller to bond the treated bonding layer with the nitrogen groups and the hydroxyl groups to a second wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G illustrate wafers during various steps of a method of bonding wafers using a surface activation plasma (SAP) treatment to increase nitrogen concentration of bonding layers in accordance with an embodiment of this disclosure;

FIGS. 2A-2C illustrate a wafer during various steps of the SAP treatment to increase nitrogen concentration of bonding layers in accordance with an embodiment of this disclosure;

FIG. 3 is a flowchart illustrating the method of bonding wafers illustrated in FIGS. 1A-1G using the SAP treatment to increase nitrogen concentration of bonding layers illustrated in FIGS. 2A-2C in accordance with an embodiment of this disclosure;

FIG. 4 is a schematic diagram of a surface activation plasma (SAP) module which may be used to perform the SAP treatment to increase nitrogen concentration of bonding layers of FIGS. 2A-2C in accordance with an embodiment of this disclosure;

FIG. 5 is a flowchart illustrating a method of bonding wafers using a SAP treatment to increase nitrogen concentration of bonding layers in accordance with an embodiment of this disclosure; and

FIG. 6 is a flowchart illustrating a method of bonding wafers using a SAP treatment to increase nitrogen concentration of bonding layers in accordance with an embodiment of this disclosure.

### DETAILED DESCRIPTION OF ILLUSTRATIVE EMBODIMENTS

Bonding processes may introduce non-linear distortions in a device wafer pattern. These distortions can lead to misalignments in subsequent lithography steps, potentially resulting in missed connections and compromised device performance. Current surface activation plasma (SAP) treatments, while effective in achieving high bonding energy, often contribute to increased wafer warpage and in-plane distortion after bonding. This warpage and distortion can exceed acceptable tolerances for advanced semiconductor manufacturing processes.

The approach described in this disclosure involves modifying surface activation plasma (SAP) parameters to reduce post-bond distortion in bonding processes. In various embodiments, the method leverages the correlation between increased nitrogen concentration on the wafer surface and reduced post-bond wafer warpage and in-plane distortion. By carefully tuning SAP parameters such as plasma power, exposure time, chamber pressure, and gas flow rates, the SAP treatment can increase the surface nitrogen concentration while maintaining adequate bonding energy. This approach allows for a more controlled and uniform bond propagation, resulting in a more even post-bond stress distribution with lower total stress and warpage. The increased nitrogen concentration on the surface decreases the bonding front propagation speed without diminishing the quality of the bonding energy between the bonded wafers. This slower, more controlled bonding process contributes to reduced distortion and improved uniformity. This technique is compatible with existing surface preparation processes and can be implemented in conjunction with a bonding tool, potentially offering improvements in die-to-die overlay accuracy for advanced semiconductor manufacturing processes.

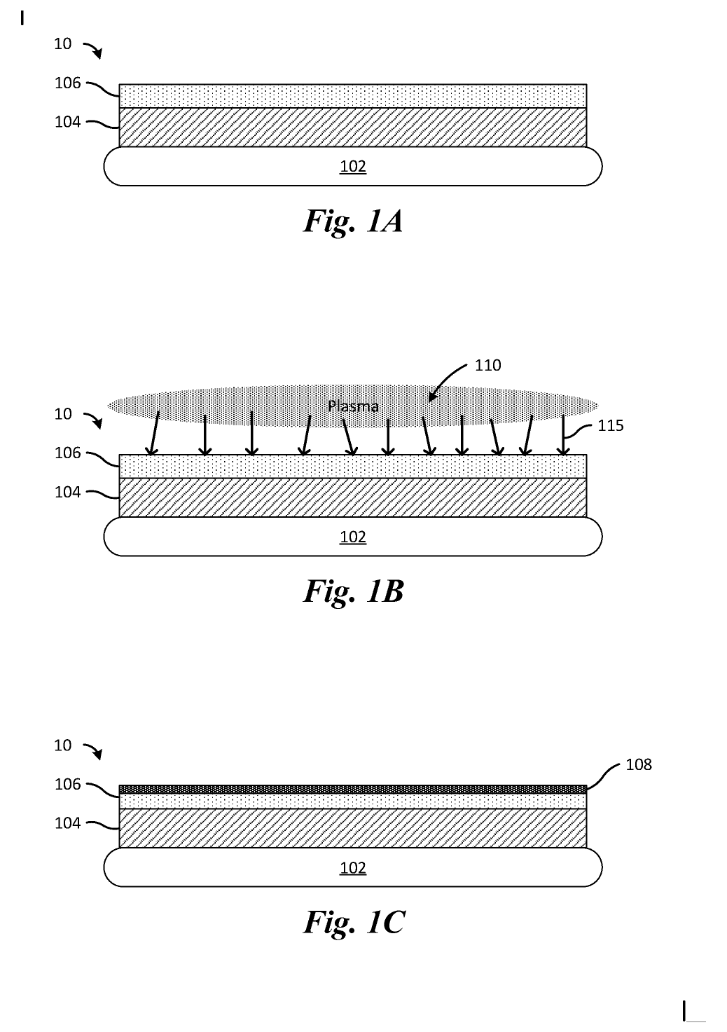

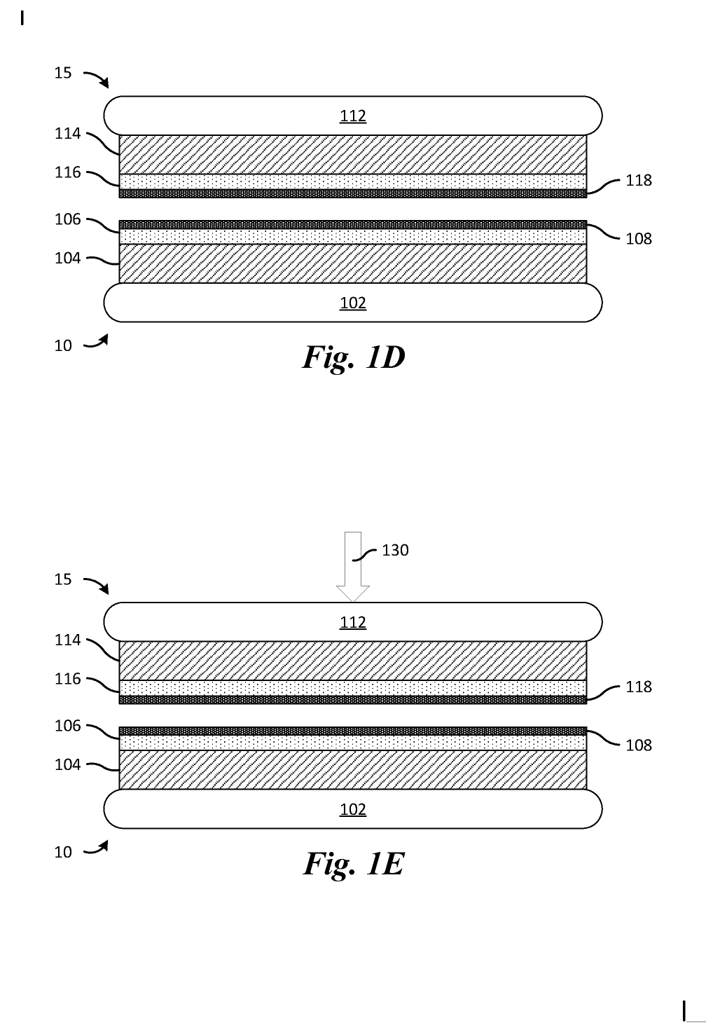

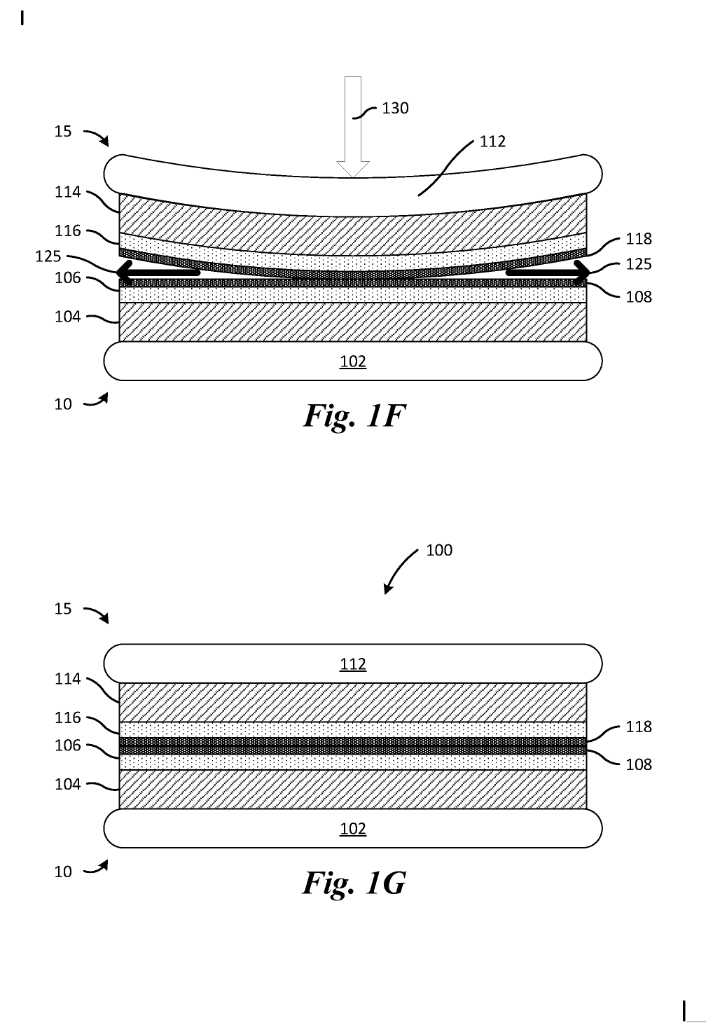

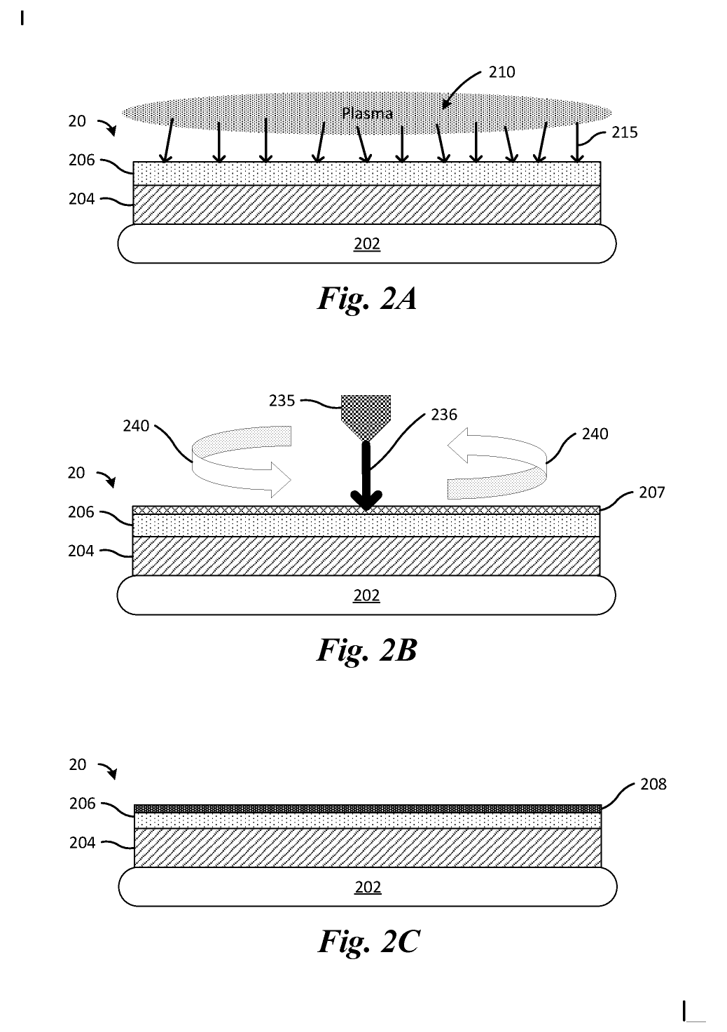

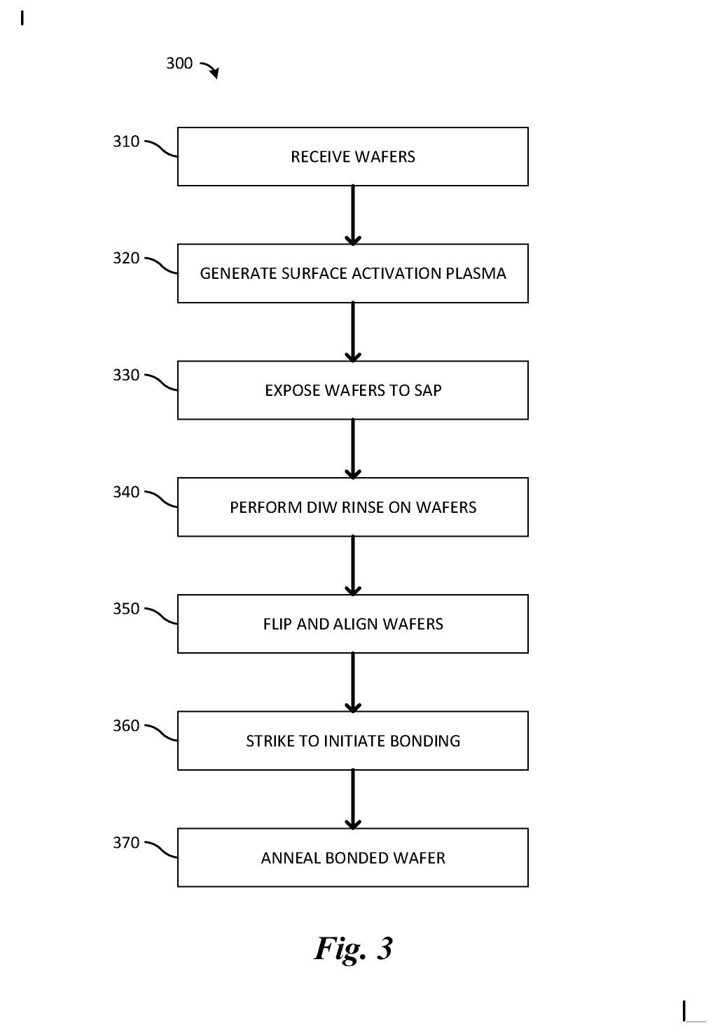

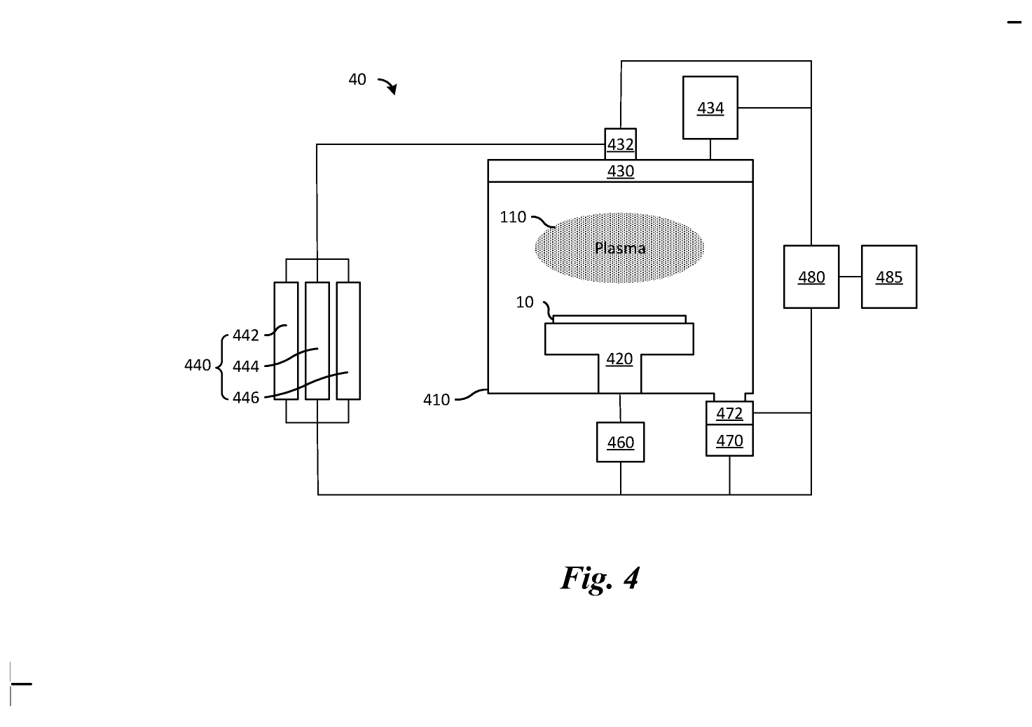

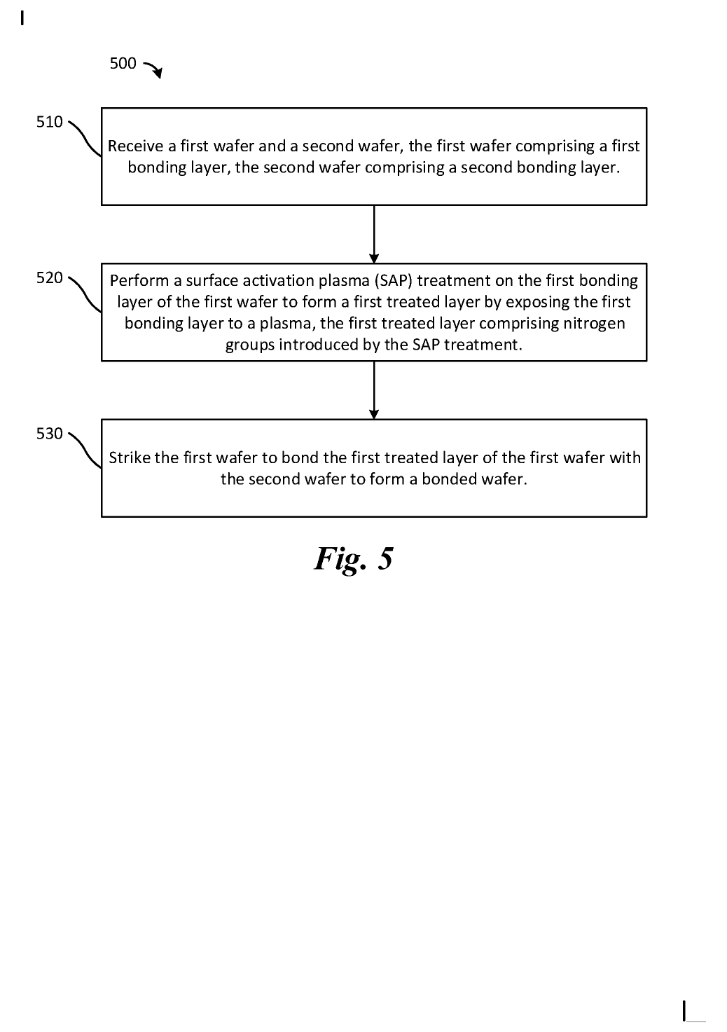

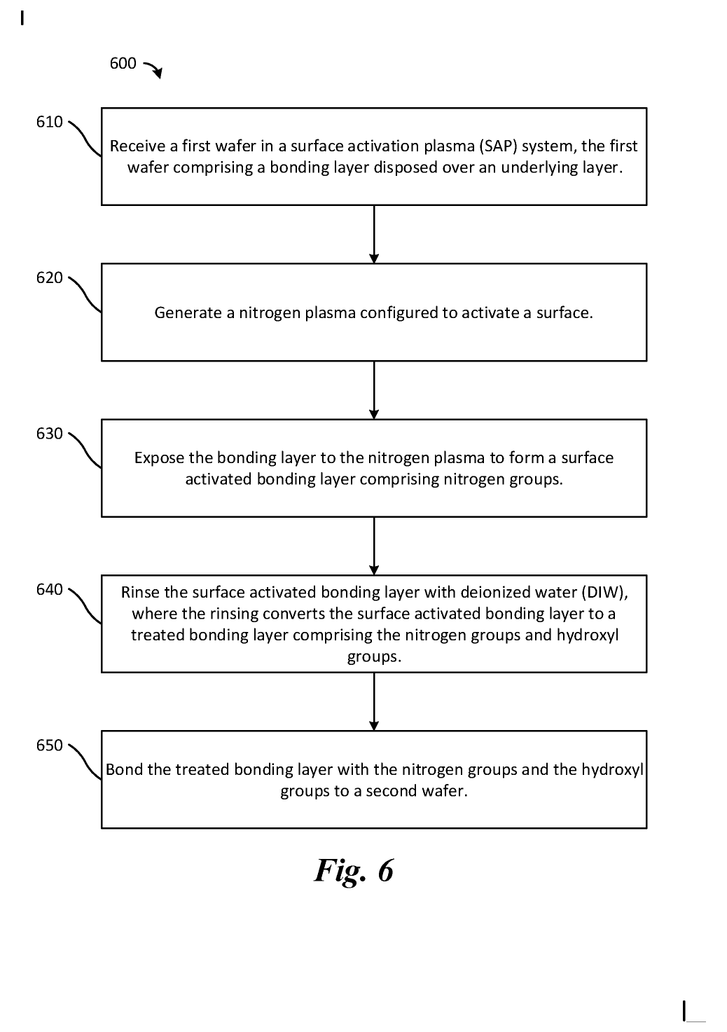

Embodiments provided below describe various methods, apparatuses and systems for bonding, and in particular, to methods, apparatuses, and systems for bonding that use a SAP treatment to increase nitrogen concentration on bonding layers to reduce device warpage. The following description describes the embodiments. FIGS. 1A-1G describe an example bonding method that uses a SAP treatment to increase nitrogen concentration of bonding layers. FIGS. 2A-2C describe an embodiment surface activation plasma (SAP) treatment which may be used in the bonding method of FIGS. 1A-1G. FIG. 3 is a flowchart used to describe the bonding method of FIGS. 1A-1G, which comprises descriptions for the SAP treatment of FIGS. 2A-2C. An example system capable of implementing the SAP treatment of the bonding method of this disclosure is described using FIG. 4. And the flowcharts of FIGS. 5-6 illustrate two other example bonding methods comprising a SAP treatment to increase nitrogen concentration of the bonding layers before bonding in accordance with embodiments of this disclosure.

FIGS. 1A-1G illustrate wafers during various steps of a method of bonding wafers using a surface activation plasma (SAP) treatment to increase nitrogen concentration of bonding layers in accordance with an embodiment of this disclosure. In various embodiments, the method of bonding wafers may begin in FIG. 1A, where a first wafer 10 is received in a surface activation plasma (SAP) module.

Now referring to FIG. 1A, the first wafer 10 may be received in a SAP module to perform the SAP treatment to increase nitrogen concentration of a bonding layer. The first wafer 10 comprises a first underlying layer 104 disposed over a first substrate 102, and a first bonding layer 106 disposed over the first underlying layer 104. In various embodiments, the first wafer 10 is received as illustrated in FIG. 1A in the SAP module after performing various processes to form the various layers of the first wafer 10.

In one or more embodiments, the first substrate 102 may be a silicon wafer, or a silicon-on-insulator (SOI) wafer. In certain embodiments, the first substrate 102 may comprise a silicon germanium wafer, silicon carbide wafer, gallium arsenide wafer, gallium nitride wafer and other compound semiconductors. In other embodiments, the first substrate 102 comprises heterogeneous layers such as silicon germanium on silicon, gallium nitride on silicon, silicon carbon on silicon, as well layers of silicon on a silicon or SOI substrate. In various embodiments, the first substrate 102 may be a component of, or comprise, a semiconductor device (e.g., a transistor), and may have undergone a number of steps of processing following, for example, a conventional process. For example, the first wafer 10 may comprise the first substrate 102 in which various device regions are formed.

In various embodiments, the first underlying layer 104 may be a metallization layer, or a plurality of metallization layers. Further, the first underlying layer 104 may be formed using a conventional process using suitable deposition, patterning, and etching techniques to form the first underlying layer 104. In various embodiments, the first underlying layer 104 may comprise a dielectric material. In certain embodiments, the first underlying layer 104 may be a silicon oxide layer. In alternate embodiments, the first underlying layer 104 may comprise silicon nitride, silicon oxynitride, or an O/N/O/N layer stack (stacked layers of oxide and nitride). The first underlying layer 104 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the first underlying layer 104 has a thickness between 1 µm and 10 µm. In another embodiment, the first underlying layer 104 may comprise a back end of line (BEOL) layer disposed over a front end of line (FEOL) layer.

In one or more embodiments, the first bonding layer 106 may be any suitable bonding material deposited through a deposition process. For example, in various embodiments, the first bonding layer 106 may comprise tetraethyl orthosilicate (TEOS), silicon oxide, silicon nitride, silicon oxynitride, polymers, organic adhesive layers, or glass.

After receiving the first wafer 10 in the SAP module, the bonding method may perform a surface activation plasma (SAP) treatment of the first wafer 10, such as illustrated in FIG. 1B. The SAP treatment may generate a plasma 110 using an RF power supply to ignite a nitrogen precursor into the plasma 110. Once generated, the SAP treatment exposes the first wafer 10 to plasma species 115 of the plasma 110 to form nitrogen groups on a surface of the bonding layer 106. The inventors of this application have identified that contrary to expectation that addition of nitrogen will likely form nitrogen terminated sites that lowers bonding strength between wafers, introducing nitrogen precursor can have a beneficial effect.

The SAP treatment of FIG. 1B may be described further using FIGS. 2A-2C. In one or more embodiments, the plasma species 115 comprises electrons, ions, and various reactive nitrogen species which may form nitrogen groups on the bonding layer 106, where the nitrogen groups comprise inactive nitrogen termination sites (such as a Si-N termination site). SAP parameters of the SAP treatment may be controlled and varied during the SAP treatment to form a nitrogen rich bonding layer on the first wafer 10. For example, the SAP parameters may comprise a plasma power, a wafer temperature, a plasma frequency, a precursor gas flow rate, a chamber pressure, and an exposure time. And in various embodiments, the plasma frequency may comprise 13.56MHz, the plasma power may be between 400W and 1000W, and the wafer temperature may be between 25˚C and 400˚C. Additionally, the SAP treatment of the step illustrated in FIG. 2B may further comprise a deionized water (DIW) rinse to form hydroxyl groups on the surface of the bonding layer 106. In other embodiments, the plasma frequency may vary between 2MHz and 300MHz as desired.

In one or more embodiments, during the exposure of the first wafer 10 to the plasma 110, nitrogen reactive species of the plasma species 115 may interact with the surface of the bonding layer 106. This interaction may modify the surface chemistry of the bonding layer 106 by introducing nitrogen-containing functional groups or by enhancing existing surface characteristics. As a result, the nitrogen groups formed on the surface of the first bonding layer 106 may be self terminating such that hydroxyl group formation is limited.

Now referring to FIG. 1C, in various embodiments, the SAP treatment forms a first treated bonding layer 108 comprising nitrogen groups and hydroxyl groups on the first bonding layer 106. As an example, in an embodiment where the first bonding layer 106 comprises tetraethyl orthosilicate (TEOS), the SAP treatment may form nitrogen groups comprising SiₓN_{y} and SiOₓN_{y}. And in that embodiment, the nitrogen groups may be self terminating (or function as inactive nitrogen terminations sites) such that a high nitrogen concentration is formed in the first treated bonding layer 108. Because of this effect, it is expected that such a process when used will cause a lowering of bond strength when two such wafers are bonded. However, the inventors of this application have surprisingly found a contrary effect when nitrogen is introduced as the SAP gas as described in various embodiments of this application.

After forming the first treated bonding layer 108, the bonding method may perform a similar SAP treatment process on a second wafer 15 and then load the second wafer 15 and the first wafer 10 in a bonding tool, such as illustrated in FIG. 1D. In various embodiments, the second wafer 15 may be aligned over the first wafer 10 in the bonding tool, where the second wafer may be brought within a configurable separation distance to prepare the wafers to be bonded.

As illustrated in FIG. 1D, the second wafer 15 comprises a second substrate 112, a second underlying layer 114, and a second bonding layer 116 comprising a second treated bonding layer 118. In one or more embodiments, the various layers and substrates of the second wafer 15 may be as previously described for the first wafer 10 in FIGS. 1A-1C. In particular embodiments, the first wafer 10 may be a carrier wafer and the second wafer 15 may be a device wafer comprising front end of line (FEOL) layers and signal back end of line (BEOL) layers suitable for forming a back-side power delivery network (BS-PDN).

Now referring to FIG. 1E, after aligning the second wafer 15 over the first wafer 10 in the bonding tool, the bonding method may use a striker of the bonding tool to strike 130 a backside of the second wafer 15 into the first wafer 10 to initiate the bonding process. In various embodiments, the bonding tool may be a direct bonding tool, a fusion bonding tool, or an adhesion bonding tool.

In FIG. 1F, the strike 130 initiates a bond front 125, which may propagate from an initial bonding region to outer edges of the wafers, where the initial bonding region is a region where the second treated bonding layer 118 of the second wafer 15 meets the first treated bonding layer 108 of the first wafer 10. The striker initiates bonding as the hydroxyl groups between the wafer surfaces make contact and form van der Waals bonds between the wafer surfaces. The bond front propagates through the wafer surfaces due to the attraction of the van der Waals bond. The high nitrogen concentration in the first treated bonding layer 108 and the second treated bonding layer 118 causes a lower adhesion energy between the first wafer 10 and the second wafer 15, thus the bond front 125 of the bonding method in this disclosure propagates at a slower rate than conventional methods.

As a result of the slower bond front 125 propagation speed, the bonding method of this disclosure may reduce wafer distortions of the first wafer 10 and the second wafer 15 during and after the bonding. Consequently, the bonding method of this disclosure may reduce the occurrence of feature misalignment, and thus reduce misalignments in subsequent lithographic patterning steps and feature formation steps.

FIG. 1G illustrates a bonded wafer 100 formed using the bonding method of this disclosure. In various embodiments, the bonded wafer 100 comprises the well aligned first wafer 10 and the second wafer 15 after the bond front 125 finished propagating to form the bonded wafer 100. The bonded wafer 100 has been formed with decreased distortions (and thus may prevent misalignments) by using the SAP treatment of this disclosure to form first treated bonding layer 108 and second treated bonding layer 118 comprising high nitrogen concentrations. Further, the high nitrogen concentration of the treated layers used to bond the first wafer 10 and the second wafer 15 form the bonded wafer 100 without sacrificing the high bonding energy of conventional methods, which is another benefit of this disclosure.

In various embodiments, after forming the bonded wafer 100, the bonding method may further comprise an annealing step to strengthen bonds between the first wafer 10 and the second wafer 15. Additionally, the bonding method may further comprise an edge trimming and a backside thinning step to remove the second substrate 112 and reveal potential backside contacts (not shown) disposed in the second wafer 15. And in even further embodiments, after the backside thinning step, a back-side power delivery network (BS-PDN) may be formed over the bonded wafer 100 using suitable deposition, etch, and patterning techniques.

FIGS. 2A-2C illustrate a wafer 20 during various steps of a SAP treatment to increase nitrogen concentration of a bonding layer 206. The SAP treatment may begin in FIG. 2A.

Now referring to FIG. 2A, the SAP treatment may begin by receiving the wafer 20 in a SAP module and exposing the wafer 20 to a plasma 210. The wafer 20 comprises an underlying layer 204 disposed over a substrate 202, and the bonding layer 206 disposed over the underlying layer 204. In various embodiments, the various layers of the wafer 20 may be formed using various conventional processes, such as previously described for the first wafer 10 in FIG. 1A. Similarly, the composition of the various layers of the wafer 20 may be as previously described for the layers of the first wafer 10 or the second wafer 15.

After receiving the wafer 20 in the SAP module, the SAP module may generate the plasma 210 using an RF power source to ignite a nitrogen containing precursor gas. For example, an RF power with a frequency of 13.56MHz may be applied to a top electrode to ignite the nitrogen containing precursor gas into the plasma 210, the plasma 210 comprising ions, electrons, and various reactive nitrogen species. The plasma 210 may be a SAP in various embodiments. Once the plasma 210 is generated, the wafer 20 may be exposed to the plasma 210 to interact with a surface of the bonding layer 206 to form nitrogen groups on the surface of the bonding layer 206. In various embodiments, SAP parameters of the plasma, such as exposure time, power level, RF frequency, pressure, wafer temperature, and flow rates of various precursor gases may be controlled to achieve a desired nitrogen concentration level on the surface of the bonding layer 206. In one or more embodiments, the power level of the RF power used to form the plasma 210 may be between 400W and 1000W.

In one or more embodiments, the precursor gases used to form the plasma 210 may further comprise oxygen containing gases such that hydroxyl groups may also be formed on the surface of the bonding layer 206 as desired. Further, variations in power level for the plasma 210 may form particular surface groups with a higher preference than other groups. For example, a high power for the plasma 210 may form a higher concentration of nitrogen groups on the surface of the bonding layer 206 than hydroxyl groups. Consequently, the ratio of nitrogen groups to hydroxyl groups formed on the surface of the bonding layer 206 may be controlled by varying SAP parameters during the exposure to the plasma 210. In other embodiments, after generating the plasma, a noble gas such as helium or argon may be introduced to the plasma, which may increase a plasma density of the plasma. In those embodiments, the increased plasma density may increase the amount of nitrogen groups formed which increases a nitrogen concentration (amount of nitrogen groups) formed on the surface of the bonding layer 206.

Additionally, in various embodiments, the nitrogen groups comprise inactive nitrogen termination sites, which may self terminate, and which may aid in limiting the number of hydroxyl groups formed on the surface of the bonding layer 206. As an example, in an embodiment where the bonding layer 206 comprises tetraethyl orthosilicate (TEOS), the nitrogen groups formed on the surface may comprise SiₓN_{y} and SiOₓN_{y} groups which may limit the amount of hydroxyl groups formed by the SAP treatment.

Now referring to FIG. 2B, the exposure to the plasma 210 in FIG. 2A formed a SAP treated bonding layer 207 on the surface of the bonding layer 206. After forming the SAP treated bonding layer 207, the SAP treatment may then transfer the wafer 20 to a spin-coating apparatus to perform a deionized water (DIW) rinse on the surface of the SAP treated bonding layer 207. As illustrated in FIG. 2B, the DIW rinse may perform a center flow 236 of DIW over the wafer 20 from a fluid nozzle 235 configured to flow DIW at a preconfigured flow rate. And during the flowing, the spin-coating apparatus may perform rotations 240 to fully and uniformly coat the surface of the wafer 20 while emitting the DIW in the center flow 236.

The DIW rinse may be used to aid the formation of hydroxyl groups on the SAP treated bonding layer 207 of the wafer 20, and parameters of the DIW rinse may be configured to achieve a desired amount of hydroxyl groups on the SAP treated bonding layer 207. Additionally, the DIW rinse may remove residual chemicals which may have formed as by-products from the plasma 210 interacting with the bonding layer 206 of the wafer 20. Further, the DIW rinse may also hydrate the treated bonding layers, stabilize hydroxyl groups formed in the SAP treated bonding layer 207, and may also aid in pH neutralization of surface pH of the wafers. Various rinse parameters may be controlled during the DIW rinse to control the hydroxyl groups formed on the surface of the SAP treated bonding layer 207, such as the rotation rate of the rotations 240, the DIW flow rate from the fluid nozzle 235, as well as vacuum conditions of the spin-coating apparatus.

In various embodiments, the DIW rinse may form a treated bonding layer 208, which is illustrated in FIG. 2C. FIG. 2C illustrates the wafer 20 after completing the SAP treatment of this disclosure. The bonding layer 206 was exposed to the plasma 210 to form nitrogen groups and hydroxyl groups on the SAP treated bonding layer 207, which then underwent a DIW rinse to further form hydroxyl groups as desired and remove contaminants and other by-products from the surface of the wafer 20 to form the treated bonding layer 208. In various embodiments, the wafer 20 illustrated in FIG. 2C is ready to be bonded with another wafer or die as may be desired.

In one or more embodiments, the SAP treatment illustrated in FIGS. 2A-2C may be the SAP treatment performed in FIG. 1B to form the first treated bonding layer 108 in FIG. 1C. The ability of the SAP treatment of this disclosure to form desired nitrogen concentrations of the treated bonding layer 208 causes bond fronts to propagate at a slower rate, which enables the formation of bonded wafers with less distortion.

As described using FIGS. 2A-2C, the SAP treatment of this disclosure may be used to balance adequate bonding energy and reduced bonding distortion by configuring SAP parameters to form desired nitrogen concentration on the surface of bonding layers. The ability of the SAP treatment to enable less distorted bonded wafers by increasing nitrogen group formation (or nitrogen concentration) to decrease the bond front propagation rate is a benefit of the bonding method and the SAP treatment of this disclosure. Another benefit of the SAP treatment is that the bonded wafers comprise a more uniform post-bond stress distribution with lower total stress and wafer warpage due to the increased nitrogen concentration of the treated bonding layer 208. In various embodiments, the SAP treatment may be configured to form the treated bonding layer 208 comprising a total nitrogen concentration between 2% to 10%. And a ratio of hydroxyl groups to nitrogen groups of the treated bonding layer 208 may be between 7:5 (oxygen rich) and 1:5 (nitrogen rich).

FIG. 3 is a flowchart illustrating a method 300 of bonding wafers using a SAP treatment to increase nitrogen concentration on bonding layers of wafers to be bonded. In various embodiments, the method 300 may begin by receiving wafers in step 310. In an embodiment, the wafers received in step 310 may be the first wafer 10 and the second wafer 15 of FIGS. 1A-1G, and the receiving of the wafers may be illustrated by FIG. 1A.

After receiving the wafers in step 310, the method 300 may proceed to step 320. In step 320, the method 300 generates a surface activation plasma (SAP). In various embodiments, the SAP may be generated using a SAP module using configurable SAP parameters. In one or more embodiments, the SAP may be the plasma 110 of FIG. 1B, or the plasma 210 of FIG. 2A.

In various embodiments, the SAP may be a nitrogen plasma generated using an RF power to ignite a nitrogen precursor gas to form the SAP. In those embodiments, the RF power and other SAP parameters of the SAP may be configured to control the formation of hydroxyl groups and nitrogen groups once the wafers are exposed to the SAP. As an example, in various embodiments, increased RF power may enable the formation of an increased amount of nitrogen groups and a decreased amount of hydroxyl groups. In other embodiments, after generating the SAP, introducing a noble gas such as helium or argon to the SAP may increase a plasma density of the SAP. In those embodiments, the increased plasma density may increase the amount of nitrogen groups formed which increases a nitrogen concentration formed on exposed surfaces of the wafers.

In step 330, the method 300 exposes the wafers to the SAP. Various SAP parameters may be configured and tuned during the exposure in step 330 to enable the SAP treatment to control the formation of hydroxyl groups and nitrogen groups on bonding layers of the wafers. For example, in various embodiments, a high RF power may form a large amount of nitrogen groups in the bonding layers of the wafers. In other embodiments, various SAP parameters (such as exposure time, wafer temperature, gas flow rates, and RF power) may be controlled to form the desired amounts of hydroxyl groups and nitrogen groups on the bonding layers of the wafers. In step 330, the method 300 exposes the wafers to the SAP using SAP parameters to form a large amount of nitrogen groups on the bonding layers to form SAP treated bonding layers comprising a larger amount of nitrogen groups than conventional SAP treatments.

In various embodiments, the larger amount of nitrogen groups decreases adhesion energy during the bonding of the wafers, which may slow bond front propagation when bonding the wafers. And a bonded wafer formed by bonding wafers comprising a large amount of nitrogen groups in the SAP treated bonding layers may result in a more uniform bond and decreased wafer distortion between the wafers of the bonded wafer. In an embodiment, the SAP treated bonding layer formed from the exposure in step 330 may be the SAP treated bonding layer 207 illustrated in FIG. 2B.

After exposing the wafers to the SAP in step 330, the method 300 may proceed to step 340. In step 340, the method 300 performs a deionized water (DIW) rinse on the wafers. The DIW rinse may aid the formation of the hydroxyl groups on the SAP treated bonding layers of the wafers, and parameters of the DIW rinse may be configured to achieve a desired amount of hydroxyl groups on the SAP treated bonding layers. Additionally, the DIW rinse may remove residual chemicals which may have formed as by-products from the SAP interacting with the bonding layers of the wafers during the exposing in step 330. Further, the DIW rinse may also hydrate the treated bonding layers, stabilize hydroxyl groups formed in the treated bonding layers, and may also aid in pH neutralization of surface pH of the wafers. The DIW rinse in step 340 forms treated bonding layers on the wafers. In various embodiments, the DIW rinse in step 340 may be illustrated by FIGS. 2B-2C, and the treated bonding layers formed by the DIW rinse may be the treated bonding layer 208 in FIG. 2C or the first treated bonding layer 108 in FIG. 1C.

The SAP treatment to increase nitrogen concentration on bonding layers of this disclosure comprises the steps 320, 330, and 340. And after performing the SAP treatment of steps 320, 330, and 340, the method 300 may proceed to step 350.

In step 350, the method 300 may transfer the wafers to a bonding apparatus or bonding tool, where one of the wafers is flipped over the other wafer. Further, in step 350, the wafers may be aligned using conventional methods such that one wafer is disposed over the other wafer and brought within a preconfigured separation distance suitable for initiating bonding of the wafers. In various embodiments, the step 350 may be illustrated as the step in FIG. 1D.

And in step 360, the method 300 strikes one of the wafers into the other to initiate bonding. In various embodiments, this may be done using a bonding tool comprising a striker which may strike a center region of the top wafer into the bottom wafer to initiate a bond front. Further, step 360 of the method 300 may be illustrated as the step in FIGS. 1E-1F.

As a result of the higher concentration of nitrogen groups on bonding layers of the wafers from the SAP treatment, the bond front may propagate at a slower rate due to the lower adhesion energy from the smaller quantity of hydroxyl groups formed on the bonding layers. And consequently, a bonded wafer may be formed with less wafer distortion, which is a benefit of the bonding method and SAP treatment of this disclosure. And the bonded wafer formed in step 360 may be illustrated by the bonded wafer 100 of FIG. 1G.

After bonding the wafers in step 360, the method 300 may proceed to step 370. And in step 370, the method 300 anneals the bonded wafer. The annealing may be performed to finish forming the bonded wafer, where the bonded wafer is heated to complete the bonding process and form bonds comprising higher bonding energies.

Any suitable annealing process may be performed to finish forming the bonded wafer. In further embodiments, additional processing steps may be performed after the annealing in step 370, such as by performing additional thinning, etching, depositing, and patterning steps to form a BS-PDN. A system capable of implementing the SAP treatment of this disclosure is illustrated in FIG. 4 and described below.

FIG. 4 is a schematic diagram of a surface activation plasma (SAP) module 40 which may be used to perform the SAP treatment to increase nitrogen concentration of bonding layers of wafers described using FIGS. 1A-1G, FIGS. 2A-2C, and FIG. 3. The SAP module 40 comprises a SAP chamber 410, a vacuum pump 470 coupled to the SAP chamber 410 by a gate valve 472, a controller 480, a memory 485, an RF power supply 434, a temperature control system 460, and a gas system 440 coupled to the SAP chamber 410 by a gas inlet 432.

The SAP chamber 410 comprises a top electrode 430 and a wafer holder 420. The gas inlet 432 is coupled with the top electrode 430 to enable the injection of gases from the gas system 440 into the SAP chamber 410. In various embodiments, the gases may be used to form the plasma 110 to process the first wafer 10 disposed on the wafer holder 420. As an example, a nitrogen plasma may be generated within the SAP chamber 410 to be used in a SAP treatment, such as described using FIGS. 2A-2B.

In various embodiments, the gas system 440 may comprise a first precursor gas 442, a second precursor gas 444, and a purging gas 446. The first precursor gas 442 may comprise nitrogen, the second precursor gas 444 may comprise oxygen, and the purging gas 446 may comprise non-volatile (or inert) gases which may be used to purge the SAP chamber 410 before performing the SAP treatment, such as argon, nitrogen, hydrogen, or helium.

The SAP module 40 comprises the SAP chamber 410 configured to sustain plasma directly above the first wafer 10 loaded onto the wafer holder 420. A process gas may be introduced to the SAP chamber 410 through the gas inlet 432 and may be pumped out of the SAP chamber 410 through the vacuum pump 470 by controlling the gate valve 472 and the vacuum pump 470 using the controller 480. The gas inlet 432 may comprise a set of multiple gas inlets. The gas flow rates and chamber pressure may be controlled by the gas system 440 coupled to the gas inlet 432. The gas system 440 may comprise various components such as high pressure gas canisters, valves (e.g., throttle valves), pressure sensors, gas flow sensors, vacuum pumps, pipes, and electronically programmable controllers. The RF bias power supply 434 may be coupled to the top electrode 430. In an embodiment, an RF bias power supply (not shown) may be coupled to the wafer holder 420.

In FIG. 4, the gas inlet 432 is an opening in the top electrode 430. In one or more embodiments, the wafer holder 420 may be conductive and electrically connected to the system ground (a reference potential). In various embodiments, the wafer holder 420 may be any device suitable for holding a device during the SAP treatment, and bonding of wafers, such as an electrostatic chuck (ESC).

The temperature control system 460 may be used to control the wafer temperature of the first wafer 10 during the SAP treatment. In various embodiments, the wafer temperature may be a SAP parameter which may be configured and controlled during the SAP treatment. In one or more embodiments, the temperature control system 460 may be a resistive heating element. In other embodiments, the temperature control system 460 may be a suitable device for both cooling and heating the first wafer 10 during the SAP treatment.

In various embodiments, the controller 480 may be any suitable device for controlling the operation of the SAP module 40. Further, the controller may be coupled to various elements of the SAP module 40 to control the SAP treatment. In FIG. 4, the controller 480 is coupled with the memory 485, the RF power supply 434, the gas inlet 432, the gas system 440, the temperature control system 460, the vacuum pump 470, and the gate valve 472. The controller 480 may execute instructions stored in the memory 485 for performing the SAP treatment and may also modify, in real-time, SAP parameters of the SAP treatment based on information from the processing of the first wafer 10. In various embodiments, the memory 485 may be any suitable device for storing instructions for performing the SAP treatment and other SAP parameters and bonding methods for the bonding method of this disclosure.

The SAP module 40 is by example only. In various alternative embodiments, the SAP chamber 410 may be configured to sustain inductively coupled plasma (ICP) with RF source power coupled to a planar coil over a top dielectric cover. Alternately, other suitable configurations such as electron cyclotron resonance (ECR) plasma sources and/or a helical resonator may be used. The RF power supply 434 may be used to supply continuous wave (CW) or pulsed RF power to sustain the plasma, and may generate plasma power between 400W to 1000W. Gas inlets and outlets may be coupled to sidewalls of the SAP chamber 410, and pulsed RF power sources and pulsed DC power sources may also be used in some embodiments. In various embodiments, the RF power, chamber pressure, wafer temperature, gas flow rates and other SAP parameters may be selected in accordance with a respective process recipe.

Further, the SAP module 40 illustrated in FIG. 4 may be a module of a bonding tool, which may comprise various modules for performing the bonding method of this disclosure. For example, the SAP module 40 may be a module to receive the first wafer 10 and perform the SAP treatment, and then transfer the first wafer 10 to another module such as a spin-coater to perform the DIW rinse. And after performing the DIW rinse, the first wafer 10 may then be transferred to a bonding module of the bonding tool, which may comprise a bonding chamber to bond the first wafer with another wafer. Additionally, though wafers have been described throughout this disclosure, the SAP module 40 and the bonding tool comprising the SAP module 40 may also be used to bond dies as well as wafers.

Although not described herein, embodiments of the SAP module 40 may also be applied to remote plasma systems as well as batch systems. For example, the wafer holder 420 may be able to support a plurality of wafers that are spun around a central axis as they pass through different plasma zones.

FIGS. 5-6 are flowcharts illustrating example methods of bonding wafers using a SAP treatment to increase nitrogen concentration of bonding layers in accordance with embodiments of the disclosure. The methods of FIGS. 5-6 may be combined with other methods and performed using the systems and apparatuses as described herein. For example, the methods of FIGS. 5-6 may be implemented in the SAP module 40 of FIG. 4. Although shown in a logical order, the arrangement and numbering of the steps of FIGS. 5-6 are not intended to be limiting.

Referring to FIG. 5, step 510 of a method 500 of bonding receives a first wafer and a second wafer, the first wafer comprising a first bonding layer, the second wafer comprising a second bonding layer. In various embodiments, the first wafer may be the first wafer 10 and the second wafer may be the second wafer 15 of FIGS. 1A-1G. Further, the first bonding layer may be the first bonding layer 106 and the second bonding layer may be the second bonding layer 116.

After, in step 520, the method 500 performs a surface activation plasma (SAP) treatment on the first bonding layer of the first wafer to form a first treated layer by exposing the first bonding layer to a plasma, the first treated layer comprising nitrogen groups introduced by the SAP treatment. The SAP treatment may be the SAP treatment described using FIGS. 2A-2C, or the SAP treatment described using FIG. 1B. Additionally, the first treated layer may be the first treated bonding layer 108 of FIG. 1C. Further, the plasma may be the plasma 110 and configured to be generated from a nitrogen precursor gas, such as the first precursor gas 442 of the SAP module 40 in FIG. 4. Step 530 of the method 500 strikes the first wafer to bond the first treated layer of the first wafer with the second wafer to form a bonded wafer, such as the bonded wafer 100 of FIG. 1G. And in various embodiments, the striking of step 530 may be the strike 130 of FIGS. 1E-1F.

Now referring to FIG. 6, step 610 of a method 600 of bonding receives a first wafer in a surface activation plasma (SAP) system, the first wafer comprising a bonding layer disposed over an underlying layer. In various embodiments, the first wafer may be the first wafer 10 of FIG. 1A, and the bonding layer may be the first bonding layer 106 and the underlying layer may be the first underlying layer 104. The SAP system may be the SAP module 40 of FIG. 4, which may be a module of a larger bonding tool configured to perform all steps of the bonding method comprising the SAP treatment of this disclosure.

After, in step 620, the method 600 generates a nitrogen plasma configured to activate a surface. The nitrogen plasma may be the plasma 110 of FIG. 1B, or the plasma 210 of FIG. 2A, which may be generated using the SAP chamber 410 of the SAP module 40 in FIG. 4. Step 630 of the method 600 exposes the bonding layer to the nitrogen plasma to form a surface activated bonding layer comprising nitrogen groups. As an example, the surface activated bonding layer may be the SAP treated bonding layer 207 of FIG. 2B in an embodiment. And the method 600, in step 640, rinses the surface activated bonding layer with deionized water (DIW), where the rinsing converts the surface activated bonding layer to a treated bonding layer comprising the nitrogen groups and hydroxyl groups. In various embodiments, step 640 may be represented by FIG. 2C, and the treated bonding layer may be the treated bonding layer 208 of FIG. 2C, the first treated bonding layer 108 of FIGS. 1C-1G, or the second treated bonding layer 118 of FIGS. 1D-1G.

Still referring to FIG. 6, in step 650, the method 600 bonds the treated bonding layer with the nitrogen groups and the hydroxyl groups to a second wafer. As an example, the second wafer may be the second wafer 15 of FIGS. 1D-1G. As a result of the nitrogen groups, the bonding process may form a bond front that propagates to bond the wafers at a slower rate than conventional methods that prioritize the formation of hydroxyl groups. Consequently, the bonded wafer formed using the bonding method 500 or 600 may be formed with reduced warpage, which improves device throughput and fabrication efficiency, which are both benefits of this disclosure. In further embodiments, the methods 500 and 600 may comprise additional fabrication steps, such as an annealing process to finalize the bond formed between the bonded wafers. Additionally, a total nitrogen concentration of the treated bonding layer may be between 2% to 10%.

Example embodiments of the invention are described below. Other embodiments can also be understood from the entirety of the specification as well as the claims filed herein.

Example 1. A method for bonding wafers includes receiving a first wafer and a second wafer, the first wafer including a first bonding layer, the second wafer including a second bonding layer. The method further includes performing a surface activation plasma (SAP) treatment on the first bonding layer of the first wafer to form a first treated layer by exposing the first bonding layer to a plasma, the SAP treatment introducing nitrogen groups including inactive nitrogen termination sites on an exposed surface of the first bonding layer. And the method further includes striking the first wafer to bond the first treated layer of the first wafer with the second wafer to form a bonded wafer.

Example 2. The method of example 1, where a plasma power used to generate the plasma includes an RF power between 400W and 1000W, where the plasma includes nitrogen, and where a total nitrogen concentration of the first treated layer varies between 2% to 10%.

Example 3. The method of one of examples 1 or 2, where the SAP treatment includes generating the plasma from a nitrogen precursor gas using a plasma power, exposing the first bonding layer to the plasma to form the nitrogen groups on the first bonding layer, and after the exposing, rinsing the first bonding layer with deionized water (DIW) to form hydroxyl groups on the first bonding layer, the rinsing forming the first treated layer including the nitrogen groups and the hydroxyl groups.

Example 4. The method of one of examples 1 to 3, where the SAP treatment further includes after generating the plasma, introducing a noble gas including helium or argon to increase a plasma density of the plasma, where increasing the plasma density increases a nitrogen concentration formed on the first bonding layer.

Example 5. The method of one of examples 1 to 4, further including, before the striking, performing the SAP treatment on the second wafer to form a second treated layer.

Example 6. The method of one of examples 1 to 5, where the first bonding layer includes tetraethyl orthosilicate (TEOS), and the inactive nitrogen termination sites are part of nitrogen groups including SiₓN_{y} and SiOₓN_{y} groups.

Example 7. The method of one of examples 1 to 6, further including annealing the bonded wafer, after the annealing, edge trimming and grinding to remove a top silicon layer of the bonded wafer, and after removing the top silicon layer of the bonded wafer, etching and depositing various material to form a back-side power delivery network (BS-PDN).

Example 8. The method of one of examples 1 to 7, further including, during the SAP treatment, controlling surface activation plasma (SAP) parameters of the plasma to achieve a target nitrogen concentration on the first bonding layer, the SAP parameters including a wafer temperature, a SAP chamber pressure, a nitrogen gas flow rate, a plasma power, a plasma frequency, and an exposure time.

Example 9. The method of one of examples 1 to 8, where the plasma frequency of the plasma power varies between 2MHz and 300MHz, and where the controlling the SAP parameters of the plasma maximize a target nitrogen concentration on the first treated layer according to a minimally allowable bond strength for the bonded wafer.

Example 10. A method of bonding includes receiving a first wafer in a surface activation plasma (SAP) system, the first wafer including a bonding layer disposed over an underlying layer, and generating a nitrogen plasma configured to activate a surface. The method further includes exposing the bonding layer to the nitrogen plasma to form a surface activated bonding layer including nitrogen groups, where the nitrogen groups include inactive nitrogen termination sites, and rinsing the surface activated bonding layer with deionized water (DIW), where the rinsing converts the surface activated bonding layer to a treated bonding layer including hydroxyl groups and the nitrogen groups. And the method further includes bonding the treated bonding layer with the nitrogen groups and the hydroxyl groups to a second wafer.

Example 11. The method of example 10, where a ratio of hydroxyl groups to nitrogen groups of the treated bonding layer varies between 7:5 and 1:5, and where the nitrogen plasma includes a surface activation plasma (SAP), and where a surface activation plasma (SAP) treatment includes the generating, the exposing, and the rinsing.

Example 12. The method of one of examples 10 or 11, where the SAP treatment further includes after generating the nitrogen plasma, introducing a noble gas including helium or argon to increase a plasma density of the nitrogen plasma, where increasing the plasma density increases a nitrogen concentration formed on the bonding layer.

Example 13. The method of one of examples 10 to 12, where the bonding layer includes tetraethyl orthosilicate (TEOS), and the inactive nitrogen termination sites are part of nitrogen groups including SiₓN_{y} and SiOₓN_{y} groups.

Example 14. The method of one of examples 10 to 13, further including, during the exposing, controlling surface activation plasma (SAP) parameters of the nitrogen plasma to achieve a target nitrogen concentration on the treated bonding layer, the SAP parameters including a wafer temperature, a chamber pressure, a nitrogen gas flow rate, a plasma power, a plasma frequency, and an exposure time.

Example 15. The method of one of examples 10 to 14, where the target nitrogen concentration varies between 2% to 10%.

Example 16. A system for semiconductor processing includes a vacuum pump coupled to a surface activation plasma (SAP) chamber, the SAP chamber including a wafer holder and a top electrode, and a gas system coupled to the SAP chamber through a gas inlet, the gas system including a first precursor gas, a second precursor gas, and a purging gas. And the system further includes a temperature control system coupled to the wafer holder, an RF power supply electrically coupled to the top electrode, and a controller coupled to the RF power supply, the vacuum pump, the gas inlet, the gas system, the wafer holder, the SAP chamber, and a memory storing instructions to be executed in the controller. The instructions when executed cause the controller to receive a first wafer on the wafer holder, the first wafer including a bonding layer disposed over an underlying layer, generate a nitrogen plasma using the gas system and the RF power supply, the nitrogen plasma configured to activate a surface. The instructions when executed further cause the controller to expose the bonding layer to the nitrogen plasma to form a surface activated bonding layer including nitrogen groups, where the nitrogen groups include inactive nitrogen termination sites, and rinse the surface activated bonding layer with deionized water (DIW), where the rinse converts the surface activated bonding layer to a treated bonding layer including hydroxyl groups and the nitrogen groups. And the instructions when executed further cause the controller to bond the treated bonding layer with the nitrogen groups and the hydroxyl groups to a second wafer.

Example 17. The system of example 16, where the wafer holder includes an electrostatic chuck (ESC), the first precursor gas includes nitrogen, the second precursor gas includes oxygen, and the purging gas includes argon, nitrogen, helium, or hydrogen.

Example 18. The system of one of examples 16 or 17, where the instructions when executed further cause the controller to, before bonding the first wafer and the second wafer, perform the generating, the exposing, and the rinsing to convert a second bonding layer of the second wafer to a second treated bonding layer.

Example 19. The system of one of examples 16 to 18, where the temperature control system includes a resistive heating element, where a total nitrogen concentration of the treated bonding layer varies between 2% to 10%, and where the RF power supply generates plasma power between 400W to 1000W.

Example 20. The system of one of examples 16 to 19, where the instructions when executed further cause the controller to control surface activation plasma (SAP) parameters of the nitrogen plasma to achieve a target nitrogen concentration on the surface activated bonding layer, the SAP parameters including a wafer temperature, a chamber pressure, a nitrogen gas flow rate, a plasma power, a plasma frequency, and an exposure time.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for bonding wafers, the method comprising:
receiving a first wafer and a second wafer, the first wafer comprising a first bonding layer, the second wafer comprising a second bonding layer;
performing a surface activation plasma (SAP) treatment on the first bonding layer of the first wafer to form a first treated layer by exposing the first bonding layer to a plasma, the SAP treatment introducing nitrogen groups comprising inactive nitrogen termination sites on an exposed surface of the first bonding layer; and
striking the first wafer to bond the first treated layer of the first wafer with the second wafer to form a bonded wafer.

2. The method of claim 1, wherein a plasma power used to generate the plasma comprises an RF power between 400W and 1000W, wherein the plasma comprises nitrogen, and wherein a total nitrogen concentration of the first treated layer varies between 2% to 10%.

3. The method of claim 1, wherein the SAP treatment comprises:
generating the plasma from a nitrogen precursor gas using a plasma power;
exposing the first bonding layer to the plasma to form the nitrogen groups on the first bonding layer; and
after the exposing, rinsing the first bonding layer with deionized water (DIW) to form hydroxyl groups on the first bonding layer, the rinsing forming the first treated layer comprising the nitrogen groups and the hydroxyl groups.

4. The method of claim 3, wherein the SAP treatment further comprises:
after generating the plasma, introducing a noble gas comprising helium or argon to increase a plasma density of the plasma, wherein increasing the plasma density increases a nitrogen concentration formed on the first bonding layer.

5. The method of claim 1, further comprising, before the striking, performing the SAP treatment on the second wafer to form a second treated layer.

6. The method of claim 1, wherein the first bonding layer comprises tetraethyl orthosilicate (TEOS), and the inactive nitrogen termination sites are part of nitrogen groups comprising SiₓN_{y} and SiOₓN_{y} groups.

7. The method of claim 1, further comprising:
annealing the bonded wafer;
after the annealing, edge trimming and grinding to remove a top silicon layer of the bonded wafer; and
after removing the top silicon layer of the bonded wafer, forming a back-side power delivery network (BS-PDN).

8. The method of claim 1, further comprising, during the SAP treatment, controlling surface activation plasma (SAP) parameters of the plasma to achieve a target nitrogen concentration on the first bonding layer, the SAP parameters comprising a wafer temperature, a SAP chamber pressure, a nitrogen gas flow rate, a plasma power, a plasma frequency, and an exposure time.

9. The method of claim 8, wherein the plasma frequency of the plasma power varies between 2MHz and 300MHz, and wherein the controlling the SAP parameters of the plasma maximize a target nitrogen concentration on the first treated layer according to a minimally allowable bond strength for the bonded wafer.

10. A method of bonding, the method comprising:
receiving a first wafer in a surface activation plasma (SAP) system, the first wafer comprising a bonding layer disposed over an underlying layer;
generating a nitrogen plasma configured to activate a surface;
exposing the bonding layer to the nitrogen plasma to form a surface activated bonding layer comprising nitrogen groups, wherein the nitrogen groups comprise inactive nitrogen termination sites;
rinsing the surface activated bonding layer with deionized water (DIW), wherein the rinsing converts the surface activated bonding layer to a treated bonding layer comprising hydroxyl groups and the nitrogen groups; and
bonding the treated bonding layer with the nitrogen groups and the hydroxyl groups to a second wafer.

11. The method of claim 10, wherein a ratio of hydroxyl groups to nitrogen groups of the treated bonding layer varies between 7:5 and 1:5, and wherein the nitrogen plasma comprises a surface activation plasma (SAP), and wherein a surface activation plasma (SAP) treatment comprises the generating, the exposing, and the rinsing.

12. The method of claim 11, wherein the SAP treatment further comprises:
after generating the nitrogen plasma, introducing a noble gas comprising helium or argon to increase a plasma density of the nitrogen plasma, wherein increasing the plasma density increases a nitrogen concentration formed on the bonding layer.

13. The method of claim 10, wherein the bonding layer comprises tetraethyl orthosilicate (TEOS), and the inactive nitrogen termination sites are part of nitrogen groups comprising SiₓN_{y} and SiOₓN_{y} groups.

14. The method of claim 10, further comprising, during the exposing, controlling surface activation plasma (SAP) parameters of the nitrogen plasma to achieve a target nitrogen concentration on the treated bonding layer, the SAP parameters comprising a wafer temperature, a chamber pressure, a nitrogen gas flow rate, a plasma power, a plasma frequency, and an exposure time.

15. The method of claim 14, wherein the target nitrogen concentration varies between 2% to 10%.

16. A system for semiconductor processing, the system comprising:
a vacuum pump coupled to a surface activation plasma (SAP) chamber, the SAP chamber comprising a wafer holder and a top electrode;
a gas system coupled to the SAP chamber through a gas inlet, the gas system comprising a first precursor gas, a second precursor gas, and a purging gas;
a temperature control system coupled to the wafer holder;
an RF power supply electrically coupled to the top electrode; and
a controller coupled to the RF power supply, the vacuum pump, the gas inlet, the gas system, the wafer holder, the SAP chamber, and a memory storing instructions to be executed in the controller, the instructions when executed cause the controller to:
receive a first wafer on the wafer holder, the first wafer comprising a bonding layer disposed over an underlying layer,
generate a nitrogen plasma using the gas system and the RF power supply, the nitrogen plasma configured to activate a surface,
expose the bonding layer to the nitrogen plasma to form a surface activated bonding layer comprising nitrogen groups, wherein the nitrogen groups comprise inactive nitrogen termination sites,
rinse the surface activated bonding layer with deionized water (DIW), wherein the rinse converts the surface activated bonding layer to a treated bonding layer comprising hydroxyl groups and the nitrogen groups, and
bond the treated bonding layer with the nitrogen groups and the hydroxyl groups to a second wafer.

17. The system of claim 16, wherein the wafer holder comprises an electrostatic chuck (ESC), the first precursor gas comprises nitrogen, the second precursor gas comprises oxygen, and the purging gas comprises argon, nitrogen, helium, or hydrogen.

18. The system of claim 16, wherein the instructions when executed further cause the controller to:
before bonding the first wafer and the second wafer, perform the generating, the exposing, and the rinsing to convert a second bonding layer of the second wafer to a second treated bonding layer.

19. The system of claim 16, wherein the temperature control system comprises a resistive heating element, wherein a total nitrogen concentration of the treated bonding layer varies between 2% to 10%, and wherein the RF power supply generates plasma power between 400W to 1000W.

20. The system of claim 16, wherein the instructions when executed further cause the controller to:
control surface activation plasma (SAP) parameters of the nitrogen plasma to achieve a target nitrogen concentration on the surface activated bonding layer, the SAP parameters comprising a wafer temperature, a chamber pressure, a nitrogen gas flow rate, a plasma power, a plasma frequency, and an exposure time.
